(19) United States
(12) Patent Application Publication
(10) Pub. No.: US 2026/0341332 A1
(43) Pub. Date: Oct. 29, 2026

(54) MEMORY SYSTEM, CONTROLLER AND OPERATING METHOD THEREOF

(71) Applicant: YANGTZE MEMORY TECHNOLOGIES CO., LTD., Wuhan (CN)

(72) Inventor: Kaikai YU, Wuhan (CN)

(21) Appl. No.: 19/320,981

(22) Filed: Sep. 5, 2025

(30) Foreign Application Priority Data
Apr. 24, 2025 (CN) 2025105254712

(51) Int. Cl. G11C 11/406

(52) U.S. Cl. CPC G11C 11/40622; G11C 11/40607; G11C 11/40615

(57) ABSTRACT

A memory system includes: a controller and a memory device coupled to the controller, wherein the memory device includes a plurality of memory cell rows; and the controller is configured to: determine maximum count data among count data corresponding to respective buffered row addresses based on a refresh command being sent to the memory device; obtain M target row addresses corresponding to the maximum count data from among the respective buffered row addresses, wherein M is an integer greater than 0, and M is less than or equal to a total number of the respective buffered row addresses; and extract N target row addresses from the obtained M target row addresses, and use the extracted N target row addresses as aggressor row addresses, wherein N is less than or equal to M.

### CROSS-REFERENCE TO RELATED APPLICATIONS

The present disclosure claims priority to Chinese Patent Application No. 2025105254712, which was filed Apr. 24, 2025, and is hereby incorporated herein by reference in its entirety.

### TECHNICAL FIELD

Examples of the present disclosure relate to the field of semiconductor technologies, and in particular, to a memory system, a controller and an operating method thereof.

### BACKGROUND

Memory devices are classified into volatile memory and non-volatile memory based on whether stored data is retained during power outages, where volatile memory that loses data during power outages can include static random access memory (SRAM) and dynamic random access memory (DRAM).

Dynamic random access memory requires periodic refreshing to maintain the data stored in the memory cell. In addition, if the same row address in dynamic random access memory is accessed continuously and frequently, when the access accumulates to a certain amount, it may cause the data stored in adjacent memory cell rows to flip, which is generally referred to as a row hammer effect.

### SUMMARY

According to a first aspect of examples of the present disclosure, a memory system is provided, the memory system includes: a controller and a memory device coupled to the controller, wherein the memory device includes a plurality of memory cell rows; and the controller is configured to: determine maximum count data among count data corresponding to respective buffered row addresses based on a refresh command being sent to the memory device; obtain M target row addresses corresponding to the maximum count data from among the respective buffered row addresses, wherein M is an integer greater than 0, and M is less than or equal to a total number of the respective buffered row addresses; and extract N target row addresses from among the obtained M target row addresses, and use the extracted N target row addresses as aggressor row addresses, wherein N is an integer greater than 0, and N is less than or equal to M.

In some examples, M is an integer greater than 1, the controller includes a row address extracting circuit, and the row address extracting circuit is configured to: randomly extract one target row address among the M target row addresses based on the maximum count data being less than or equal to a preset threshold.

In some examples, the row address extracting circuit is further configured to: extract the M target row addresses based on the maximum count data being greater than the preset threshold.

In some examples, the row address extracting circuit includes a first comparing circuit and an extracting circuit coupled to the first comparing circuit; the first comparing circuit is configured to: compare the maximum count data with the preset threshold to generate a comparison result; and the extracting circuit is configured to: extract the one target row address or the M target row addresses based on the comparison result.

In some examples, the controller further includes a row address buffering circuit coupled to the row address extracting circuit; the row address buffering circuit is configured to: buffer the respective row addresses; and the extracting circuit is configured to: extract the target row address from the row address buffering circuit based on the comparison result.

In some examples, the controller further includes a row address counting circuit coupled to the row address extracting circuit, the row address extracting circuit further includes a second comparing circuit coupled to the first comparing circuit; the row address counting circuit is configured to: generate the count data corresponding to the respective buffered row addresses; and the second comparing circuit is configured to: compare the count data generated by the row address counting circuit to determine the maximum count data.

In some examples, the row address buffering circuit is further configured to: delete the buffered row addresses after the target row address is extracted; and the row address counting circuit is further configured to: reset the count data corresponding to the buffered row addresses.

In some examples, both M and N are 1.

In some examples, the controller is further configured to: generate a victim row address adjacent to the aggressor row addresses, wherein a target memory cell row, to which the victim row address points, is adjacent to memory cell rows, to which the aggressor row addresses point; and send a row hammer refresh operation command including the victim row address to the memory device, wherein the row hammer refresh operation command is configured to instruct to perform a row hammer refresh operation on the target memory cell row.

In some examples, the row hammer refresh operation command includes a row hammer activation command and a pre-charge command, and wherein the row hammer activation command is configured to instruct to perform an activation operation on the row address corresponding to the target memory cell row, and the pre-charge command is configured to instruct to perform a pre-charge operation on a column address corresponding to a selected memory cell among a plurality of memory cells in the target memory cell row.

In some examples, the memory device includes a dynamic random access memory.

According to a second aspect of examples of the present disclosure, a controller is provided, the controller includes: a row address buffering circuit, a row address counting circuit, and a row address extracting circuit, the row address buffering circuit is configured to: buffer a plurality of row addresses, the row address counting circuit is coupled to the row address buffering circuit, and the row address counting circuit is configured to: generate count data corresponding to respective buffered row addresses, the row address extracting circuit is coupled to the row address buffering circuit and the row address counting circuit respectively, and the row address extracting circuit is configured to: determine maximum count data among count data corresponding to the respective buffered row addresses based on a refresh command being sent to a memory device by the controller; obtain M target row addresses corresponding to the maximum count data from among the respective buffered row addresses, wherein M is an integer greater than 0, and M is less than or equal to a total number of the respective buffered row addresses; and extract N target row addresses from among the obtained M target row addresses, and use the extracted N target row addresses as aggressor row addresses, wherein N is an integer greater than 0, and N is less than or equal to M.

In some examples, M is an integer greater than 1, and the row address extracting circuit is configured to: randomly extract one target row address among the M target row addresses based on the maximum count data being less than or equal to a preset threshold.

In some examples, the row address extracting circuit is further configured to: extract the M target row addresses based on the maximum count data being greater than the preset threshold.

In some examples, the row address extracting circuit includes a first comparing circuit and an extracting circuit coupled to the first comparing circuit; the first comparing circuit is configured to: compare the maximum count data with the preset threshold to generate a comparison result; and the extracting circuit is configured to: extract the one target row address or the M target row addresses based on the comparison result.

In some examples, the extracting circuit is configured to: extract the target row address from the row address buffering circuit based on the comparison result.

In some examples, the row address extracting circuit further includes a second comparing circuit coupled to the first comparing circuit, and the second comparing circuit is configured to: compare the count data generated by the row address counting circuit to determine the maximum count data.

In some examples, both M and N are 1.

In some examples, the row address buffering circuit is further configured to: delete the buffered row addresses after the target row address is extracted; and the row address counting circuit is further configured to: reset the count data corresponding to the buffered row addresses.

In some examples, the controller is further configured to: generate a victim row address adjacent to the aggressor row addresses, wherein a target memory cell row, to which the victim row address points, is adjacent to memory cell rows, to which the aggressor row addresses point; and send a row hammer refresh operation command including the victim row address to the memory device, wherein the row hammer refresh operation command is configured to instruct to perform a row hammer refresh operation on the target memory cell row.

In some examples, the row hammer refresh operation command includes a row hammer activation command and a pre-charge command, and wherein the row hammer activation command is configured to instruct to perform an activation operation on the row address corresponding to the target memory cell row, and the pre-charge command is configured to instruct to perform a pre-charge operation on a column address corresponding to a selected memory cell among a plurality of memory cells in the target memory cell row.

According to a third aspect of examples of the present disclosure, an operating method of a controller is provided, the operating method includes: determining maximum count data among count data corresponding to respective buffered row addresses based on a refresh command being sent to a memory device; obtaining M target row addresses corresponding to the maximum count data from among the respective buffered row addresses, wherein M is an integer greater than 0, and M is less than or equal to a total number of the respective buffered row addresses; and extracting N target row addresses from among the obtained M target row addresses, and using the extracted N target row addresses as aggressor row addresses, wherein N is an integer greater than 0, and N is less than or equal to M.

In some examples, M is an integer greater than 1, and extracting the N target row addresses from among the obtained M target row addresses includes: randomly extracting one target row address among the M target row addresses based on the maximum count data being less than or equal to a preset threshold.

In some examples, extracting the N target row addresses from among the obtained M target row addresses further includes: extracting the M target row addresses based on the maximum count data being greater than the preset threshold.

In some examples, extracting the N target row addresses from among the obtained M target row addresses further includes: comparing the maximum count data with the preset threshold to generate a comparison result; and extracting the one target row address or the M target row addresses based on the comparison result.

In some examples, both M and N are 1.

In some examples, determining the maximum count data among the count data corresponding to the respective buffered row addresses includes: comparing the count data corresponding to the respective buffered row addresses to determine the maximum count data.

In some examples, the operating method further includes: deleting the buffered row addresses after the target row address is extracted; and resetting the count data corresponding to the buffered row addresses.

In some examples, the operating method further includes: generating a victim row address adjacent to the aggressor row addresses, wherein a target memory cell row, to which the victim row address points, is adjacent to memory cell rows, to which the aggressor row addresses point; and sending a row hammer refresh operation command including the victim row address to the memory device, wherein the row hammer refresh operation command is configured to instruct to perform a row hammer refresh operation on the target memory cell row.

In some examples, the row hammer refresh operation command includes a row hammer activation command and a pre-charge command, and wherein the row hammer activation command is configured to instruct to perform an activation operation on the row address corresponding to the target memory cell row, and the pre-charge command is configured to instruct to perform a pre-charge operation on a column address corresponding to a selected memory cell among a plurality of memory cells in the target memory cell row.

In an example of the present disclosure, the controller determines maximum count data among count data corresponding to respective buffered row addresses based on a refresh command being sent to the memory device, and obtains M target row addresses corresponding to the maximum count data from among the respective buffered row addresses, then extracts N target row addresses from among the obtained M target row addresses, and uses the extracted N target row addresses as the aggressor row addresses. In this way, in a first aspect, the controller can obtain, in advance, target row addresses which may cause a row hammer problem to be occurred in the DRAM device, and extract one or more target row addresses from the obtained target row addresses as aggressor row addresses, so as to facilitate mitigating or even avoiding the occurrence of the row hammer problem in the DRAM device, thereby improving the reliability of the data. In a second aspect, through actively avoiding the row hammer problem by the controller, the traditional passive prevention within the DRAM can be changed to active prevention by the controller, which can actively prevent, in advance, the potential occurrence of row hammer errors in the DRAM, thus facilitating reducing the possibility that the row hammer problem occurs in the memory device.

### BRIEF DESCRIPTION OF DRAWINGS

In the drawings, like reference numbers refer to like or similar parts or elements throughout the several drawings unless otherwise specified. These drawings are not necessarily drawn to scale. It should be understood that these drawings depict only some examples disclosed in accordance with the present disclosure and should not be construed as limiting the scope of the present disclosure.

FIG. 1 is a schematic diagram of a system according to an example of the present disclosure;

FIGS. 2A and 2B are schematic diagrams of a memory device according to an example o the present disclosure;

FIG. 3 is a schematic diagram of row hammer effect in a memory array according to an example of the present disclosure;

FIG. 4 is a schematic diagram of a refresh process according to an example of the present disclosure;

FIG. 5 is a schematic diagram of a memory system according to an example of the present disclosure;

FIG. 6 is a schematic diagram of latching a row address based on a random number according to an example of the present disclosure;

FIG. 7 is a schematic flowchart of an operating method of a controller according to an example of the present disclosure;

FIG. 8 is an operation flowchart of a controller according to an example of the present disclosure;

FIG. 9 is a schematic diagram of a controller sending a victim row address and a row hammer refresh operation command to a memory device according to an example of the present disclosure.

### DETAILED DESCRIPTION

For ease of understanding of the present disclosure, examples of the present disclosure will be described in more detail below with reference to the accompanying drawings. While examples of the present disclosure are shown in the accompanying drawings, it should be understood that the disclosure may be implemented in various forms and should not be limited by the specific examples set forth herein. Rather, these examples are provided to enable a more thorough understanding of the present disclosure and to fully convey the scope of the present disclosure to those skilled in the art.

In the following description, numerous specific details are given in order to provide a more thorough understanding of the present disclosure. It will be apparent to those skilled in the art, however, that the present disclosure may be practiced without one or more of these details. In some examples, to avoid confusion with the present disclosure, some technical features known in the art are not described; for example, not all features of the actual examples may be described herein, and well-known functions and structures are not described in detail.

The present disclosure will be described in more detail hereinafter with reference to the accompanying drawings. Advantages and features of the present disclosure will be more apparent from the following description and claims. It should be noted that the accompanying drawings all adopt a very simplified form and use a non-precise scale, which is only used for the purpose of conveniently and clearly explaining the examples of the present disclosure.

It will be understood that the meaning of “on,” “above,” and “over” of the present disclosure should be interpreted in a broadest manner such that “on” not only represents “on” something without intervening feature or layer therebetween (e.g., directly on something), but also includes the meaning of “on” something with intervening features or layers therebetween.

In the examples of the present disclosure, the terms “first”, “second”, “third” and the like are used to distinguish similar objects and not necessarily describe a specific sequence or order.

In the present disclosure, the term “layer” refers to a material portion of a region having a thickness. A layer may extend over the entirety of the underlying or upper structure, or may have a range that is less than that of the underlying or upper structure. Further, a layer can be a region of homogeneous or heterogeneous continuous structure with a thickness less than that of the continuous structure. For example, a layer may be located between the top and bottom surfaces of the continuous structure, or a layer may be between any pair of horizontal surfaces at the top and bottom surfaces of the continuous structure. A layer may extend horizontally, vertically, and/or along sloped surfaces. A layer may include a plurality of sub-layers.

It should be noted that, the technical solutions described in the examples of the present disclosure may be arbitrarily combined without conflict.

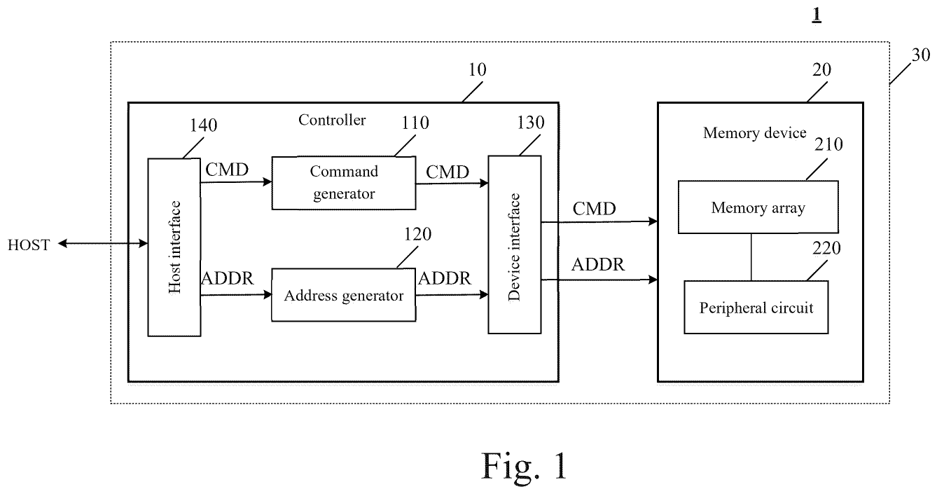

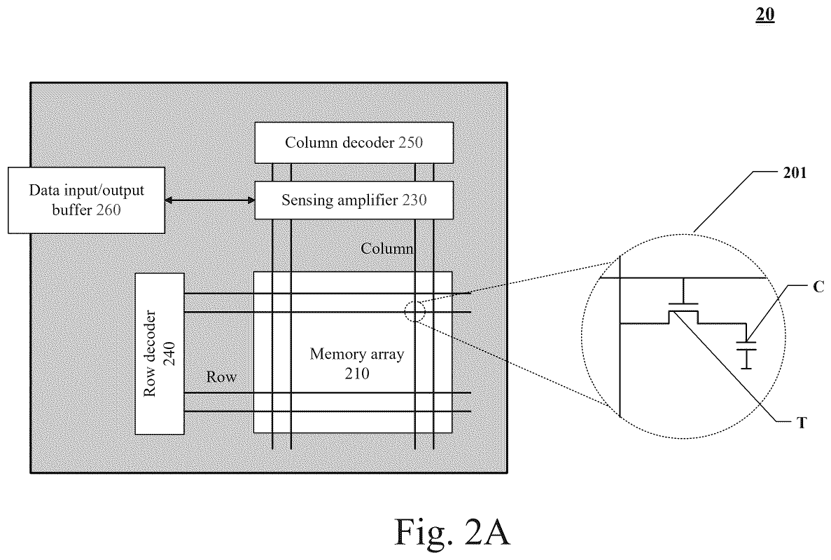

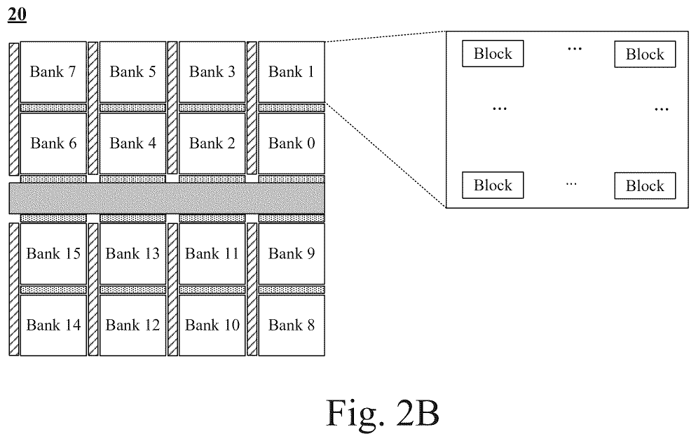

FIG. 1 is a schematic diagram of a system according to an example of the present disclosure, and FIG. 2A and FIG. 2B are schematic diagrams of a memory device according to an example of the present disclosure.

Referring to FIG. 1, the system 1 may include a host and a memory system 30. In an example of the present disclosure, the system 1 may be a mobile phone, a desktop computer, a laptop computer, a tablet computer, a vehicle computer, a game console, a printer, a positioning device, a wearable electronic device, a smart sensor, a virtual reality (VR) device, an augmented reality (AR) device, or any other suitable electronic device having a memory device therein.

The host may be a processor (for example, a central processing unit (CPU) or a system on chip (SoC) (for example, an application processor (AP)) of the electronic device. The memory system 30 has one or more memory devices 20 and a controller 10. The host may be configured to send or receive data to or from the memory device 20. The controller 10 is coupled to the memory device 20 and the host, respectively, and is configured to control the memory device 20. The controller 10 may manage data stored in the memory device 20 and communicate with the host.

The controller 10 may be configured to control operations of the memory device 20, for example, read, write, and refresh operations. In some examples, the controller 10 is further configured to process error correction codes (ECC) regarding data read from or written to the memory device 20. The controller 10 may also perform any other suitable functions, for example, formatting the memory device 20.

In some examples, the controller 10 and the one or more memory devices 20 may be integrated into various types of storage devices, for example, the controller 10 may be integrated into a northbridge of a computer motherboard or integrated directly inside a CPU of a computer, and multiple memory devices 20 may be integrated into a memory bar. For example, the memory system 30 may be implemented and packaged into different types of terminal electronics.

The controller 10 may send data to or receive data from the host, and may send a command CMD and an address ADDR to the memory device 20. The controller 10 may include a command generator 110, an address generator 120, a device interface 130, and a host interface 140. The host interface 140 may receive the command CMD and the address ADDR from the host, the command generator 110 may generate an access command, a refresh command, or the like by decoding the command CMD received from the host, and may provide the access command and the refresh command to the memory device 20 through the device interface 130. The access command may be a signal instructing the memory device 20 to write or read data by accessing a row of a memory array 210 corresponding to the address ADDR. The refresh command may instruct the memory array 210 of the memory device 20 to perform a refresh operation for the stored data.

The address generator 120 in the controller 10 may generate a row address and a column address to be accessed in the memory array 210 by decoding the address ADDR received from the host interface 140. Further, the memory device 20 may generate an address of a bank to be accessed when the memory array 210 includes multiple banks.

Further, the controller 10 may control operations of the memory device, such as write and read, by providing various signals to the memory device 20 via the device interface 130. For example, the controller 10 may provide a write command to the memory device 20. The write command is used to instruct the memory device 20 to perform a write operation to store data into the memory device 20. The memory device 20 may be a random access memory (RAM), such as dynamic random access memory (DRAM), synchronous DRAM (SDRAM), double data rate SDRAM (DDR SDRAM), DDR2 SDRAM, DDR3 SDRAM, phase change RAM (PRAM), magnetic RAM (MRAM), resistive RAM (RRAM), or the like.

Referring to FIG. 1, FIG. 2A, and FIG. 2B, the memory device 20 includes the memory array 210 and a peripheral circuit 220. The memory array 210 includes a plurality of banks, and as an example, FIG. 2B shows 16 banks, e.g., Bank0 to Bank15. Each bank includes a plurality of blocks, each block includes a plurality of memory cell rows and a plurality of memory cell columns, each memory cell row is coupled to a corresponding word line, and each memory cell column is coupled to a corresponding bit line.

The peripheral circuit 220 may include: a control circuit corresponding to each block, for example, a sensing amplifier (SA) 230 and a word-line driver (WLD), and the like; a control circuit corresponding to each bank, for example, a row decoder 240, a column decoder 250, and the like; and a control circuit corresponding to all banks, for example, a data input/output buffer 260, a command buffer, a command decoder, an address buffer, a mode register, and the like.

The peripheral circuit 220 may write data to or read data from the memory array 210 based on the command CMD and the address ADDR received from the controller 10, or may provide a control signal CTRL to the row decoder 240 and the column decoder 250 for refreshing the memory cells included in the memory array 210. In other words, the peripheral circuit 220 may perform all operations to process data in the memory array 210.

Referring to FIG. 2A, the memory device includes at least one DRAM die, each DRAM die includes the memory array 210, the memory array 210 includes a plurality of memory cells 201 arranged in an array, and each memory cell 201 includes a transistor T and a capacitor C. The main working principle of the memory cell is to use the amount of charge stored in the capacitor to represent that whether a binary bit is 1 or 0. The memory cells arranged in an array may be regarded as a typical mesh structure, where the memory array uses row and column to specify an address. By specifying the intersection of row and column (by specifying the row address and column address of the DRAM), the controller can independently access each of the memory cells in the DRAM die and perform read, write, or refresh operations on the data stored therein.

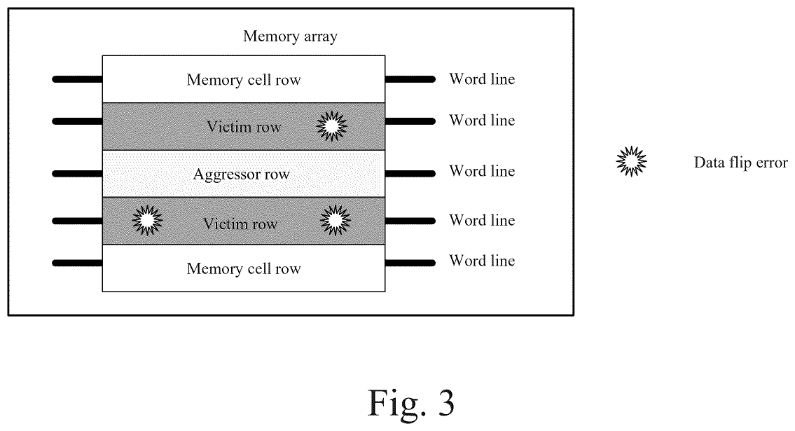

FIG. 3 is a schematic diagram of row hammer effect in a memory array according to an example of the present disclosure. Referring to FIG. 3, the memory array includes a plurality of memory cell rows, each memory cell row is coupled to a corresponding word line. Accessing a memory cell row quickly and continuously over a period of time may cause the occurrence of data flip errors on a memory cell row physically adjacent to the memory cell row being accessed. Generally, a memory cell row being accessed continuously is referred to as an aggressor row, and a physical address of the aggressor row is a row hammer address, as well as a memory cell row physically adjacent to the aggressor row and likely to occur data flip errors is referred to as a victim row, and a physical address of the victim row is a victim row address. It should be noted that, each row address corresponds to a word line, and by accessing a target row address in a plurality of row addresses, the word line corresponding to the target row address may be selected or activated.

For the row hammer effect, each DRAM device has a target parameter according to the manufacturing process and the storage density. For example, in a case that a refresh operation is not performed on memory cell rows in the DRAM, if a number of times that a certain memory cell row being continuously accessed is less than a defined target parameter, then data stored in a memory cell row physically adjacent to the memory cell row being continuously accessed is safe and reliable. Otherwise, if a number of times that a certain memory cell row being continuously accessed is greater than or equal to the target parameter, then data stored in a memory cell row physically adjacent to the memory cell row being continuously accessed may occur a data flip error, which is generally referred to as a row hammer error.

If a refresh operation is performed timely, before the accessing number that the memory cell row being continuously accessed reaches the target parameter, on the memory cell row physically adjacent to the memory cell row being continuously accessed, then the occurrence of the data flip error on the adjacent memory cell row may be avoided, for example, the occurrence of the row hammer error is avoided, thereby avoiding the occurrence of the row hammer problem. In practical applications, the target parameter of different DRAM manufacturers may be the same or different. The target parameter is typically formulated by the DRAM manufacturer in the development and design phase, and the value of the target parameter may be related to factors such as the manufacturing process used in producing the DRAM, the capacity and size of the die of the DRAM, and the like.

The refresh of DRAM is usually performed in units of rows. In a refresh cycle, a plurality of refresh commands need to be sent to the memory device to perform one refresh operation on all memory arrays in the memory device. For example, the controller sends a refresh command to the memory device, the memory device performs, based on the refresh command, a refresh operation on the memory cell rows to which several row addresses point in all the banks. Refreshing of all the banks can be achieved by continuing to send the refresh command. The refresh cycle depends on the specification of the DRAM, which is typically in milliseconds. For example, if the refresh cycle of the DRAM is 64 milliseconds, then all memory arrays in the memory device need to be refreshed once for every 64 milliseconds.

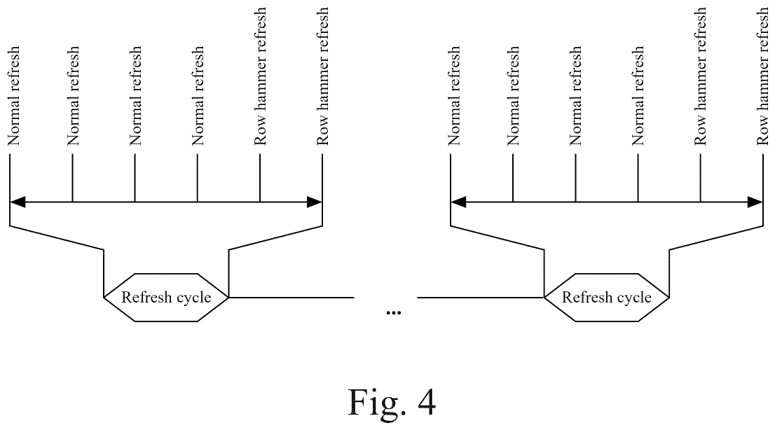

FIG. 4 is a schematic diagram of performing a refresh operation according to an example of the present disclosure. Referring to FIG. 4, the refresh operation mainly includes two parts: a first part is a normal refresh operation (Normal REF) performed to keep the data stored in the memory cells of the DRAM, where one normal refresh operation usually performs the refresh on memory cell rows to which several row addresses point, for example, the normal refresh may be performed on memory cell rows to which 4 row addresses point in each sub-bank; and a second part is a row hammer refresh (RH REF) operation performed to prevent a potential row hammer error of the DRAM from occurring, for example, the row hammer refresh may be performed on memory cell rows to which 2 row addresses point in each sub-bank. In this example, the bank may include a plurality of sub-banks, and each sub-bank includes at least one block.

In the refresh operation of the above technical solution, since the DRAM passively receives the refresh command sent by the controller, the processing of the row hammer problem (for example, finding the row address corresponding to the aggressor row and the row address corresponding to the victim row) is performed by the circuit inside the DRAM. Since the hardware resource inside the DRAM is limited, the potential possibility of occurring the row hammer error in the DRAM is relatively high, and it is difficult to completely avoid the risk of having the row hammer effect.

In addition, the row hammer effect is caused by the current high-density arrangement of DRAM memory cells, which exists in all new generations of DRAM devices (e.g., DDR, LPDDR, GDDR, HBM, etc.). The row hammer effect is a security vulnerability, which is a common problem in all new generations of DRAM devices. By quickly and continuously accessing the memory cell row to which the same row address points, the data of the adjacent memory cell row can be flipped, thereby changing the stored data. The strong attack using the row hammer effect can bypass the current safety mechanism, thereby causing problems, such as the system to be damaged or controlled and memory damage.

Based on one or more of the above technical problems, an example of the present disclosure provides a memory system.

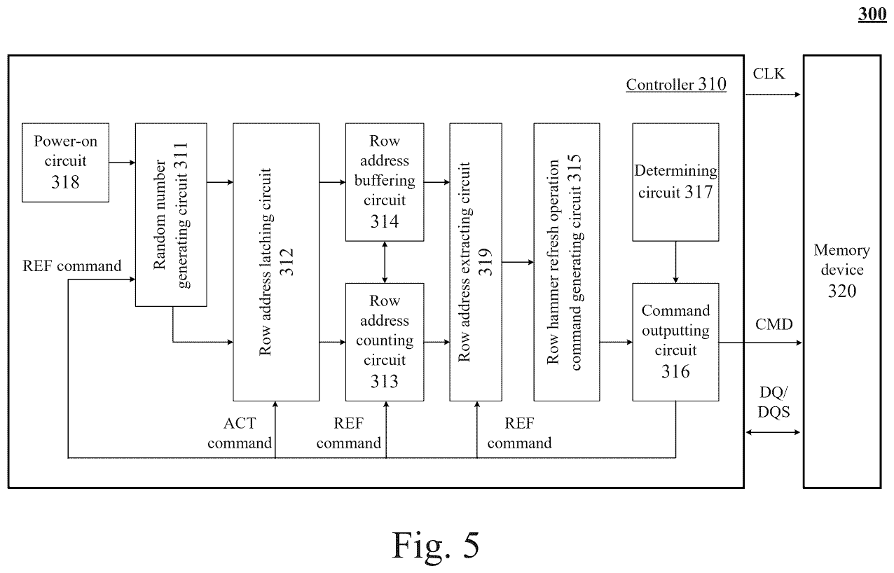

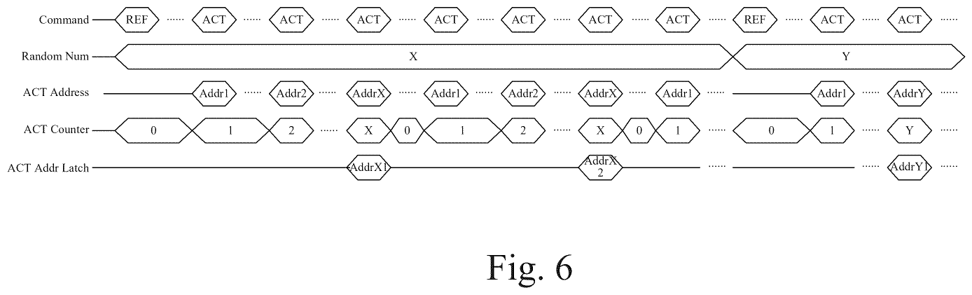

FIG. 5 is a schematic diagram of a memory system according to an example of the present disclosure. FIG. 6 is a schematic diagram of latching a row address based on a random number according to an example of the present disclosure. The memory system provided in an example of the present disclosure is described below with reference to FIG. 5 and FIG. 6.

Referring to FIG. 5, the memory system 300 includes a memory device 320, and the memory device 320 includes, but is not limited to, DRAM. The memory device 320 may include a plurality of memory cell rows, and the memory cell row include a plurality of memory cells. For the memory device 320, the memory cell row, and the memory cell, please refer to the related descriptions of the memory device 20, the memory cell row, and the memory cell 201 in FIG. 2A and FIG. 2B, respectively.

The memory system 300 further includes a controller 310, where the memory device 320 is coupled to the controller 310. The controller 310 may provide various signals to the memory device 320 through the device interface 130 shown in FIG. 1 to control operations such as write and read. For example, the controller 310 may send at least one of a command signal CMD, a clock signal CLK, and a data signal DQ/data strobe signal DQS to the memory device 320 through the device interface 130 shown in FIG. 1. The controller 310 may also receive the data signal DQ/data strobe signal DQS and the like sent by the memory device 320 through the device interface 130 shown in FIG. 1. It should be noted that the data signal DQ/data strobe signal DQS are synchronization signals, for example, the controller 310 sends the data signal DQ and the data strobe signal DQS to the memory device 320 synchronously.

In some examples, the controller 310 is configured to: determine maximum count data among count data corresponding to respective buffered row addresses based on a refresh command being sent to the memory device; obtain M target row addresses corresponding to the maximum count data from among the respective buffered row addresses, wherein M is an integer greater than 0, and M is less than or equal to a total number of the respective buffered row addresses; and extract N target row addresses from among the obtained M target row addresses, and use the extracted N target row addresses as aggressor row addresses, wherein N is an integer greater than 0, and N is less than or equal to M.

In an example of the present disclosure, the controller 310 may buffer the corresponding row address based on the received access request from the host or based on a plurality of access commands or refresh commands sent to the memory device. For example, the controller 310 may buffer a plurality of row addresses, and record the count data corresponding to the respective buffered row addresses. When the controller 310 sends the refresh command to the memory device, the controller 310 finds the maximum count data from among the recorded plurality of count data, obtains M row addresses corresponding to the maximum count data, and uses the M row addresses as the target row addresses. Then the controller 310 extracts N target row addresses from among the obtained M target row addresses, and uses the extracted N target row addresses as the aggressor row addresses (e.g., the row hammer addresses). In this way, in a first aspect, the controller 310 can obtain, in advance, target row addresses which may cause a row hammer problem to be occurred in the DRAM device, and extract one or more target row addresses from the obtained target row addresses as aggressor row addresses, so as to facilitate mitigating or even avoiding the occurrence of the row hammer problem in the DRAM device, thereby improving the reliability of the data. In a second aspect, through actively avoiding the row hammer problem by the controller 310, the traditional passive prevention within the DRAM can be changed to active prevention by the controller 310, which can actively prevent, in advance, the potential occurrence of row hammer errors in the DRAM, thus facilitating reducing the possibility that the row hammer problem occurs in the memory device.

It should be noted that, compared with other buffered row addresses, the possibility that the target row addresses corresponding to the maximum count data cause the row hammer problem to be occurred in the DRAM device is larger. Therefore, it is needed to extract the aggressor row address from the target row addresses corresponding to the maximum count data. The victim row address with a relatively large number of row hammer attacks can be determined based on the extracted aggressor row address, thereby mitigating or even avoiding the occurrence of the row hammer problem. Herein, the count data corresponding to other buffered row addresses is less than the maximum count data.

In some examples, the count data corresponding to any two row addresses among the respective buffered row addresses may be the same or different.

As an example, the count data corresponding to the plurality of row addresses among the respective buffered row addresses is the same. Further, if the count data corresponding to the plurality of row addresses is the same and is the maximum count data, there are a plurality of target row addresses, for example, M is an integer greater than 1.

As another example, the count data corresponding to any two row addresses among the respective buffered row addresses is different, for example, only the count data corresponding to one row address is the largest, and the number of target row addresses is one, for example, M is 1.

In the examples of the present disclosure, the count data corresponding to any one of the buffered row addresses is related to the number of times that the buffered row address is accessed in one refresh cycle and a random number mentioned below, for example, in one refresh cycle, if a certain row address is accessed continuously and frequently, the count data corresponding to the row address is greater. The random number will be described in detail below, and will not be repeated herein.

In some examples, the controller 310 is further configured to: generate a victim row address adjacent to the aggressor row addresses, wherein a target memory cell row, to which the victim row address points, is adjacent to memory cell rows, to which the aggressor row addresses point; and send a row hammer refresh operation command including the victim row address to the memory device, wherein the row hammer refresh operation command is configured to instruct to perform a row hammer refresh operation on the target memory cell row.

In an example of the present disclosure, the controller 310 may use the extracted N target row addresses as the aggressor row addresses, and generate the victim row address adjacent to the aggressor row addresses, then send the row hammer refresh operation command including the victim row address to the memory device. The memory device may timely refresh the victim row where the row hammer risk may exist, thereby avoiding the occurrence of the row hammer error, and facilitating ensuring the reliability of the data.

In some examples, the row hammer refresh operation command includes a row hammer activation command and a pre-charge command, wherein the row hammer activation command is configured to instruct to perform an activation operation on the row address corresponding to the target memory cell row, and the pre-charge command is configured to instruct to perform a pre-charge operation on a column address corresponding to a selected memory cell among a plurality of memory cells in the target memory cell row.

As an example, the controller 310 may send the row hammer activation command and the pre-charge command to the memory device to perform a row hammer refresh operation on the target memory cell row.

As an example, the memory device may activate the row address corresponding to the target memory cell row in response to the row hammer activation command. For example, the row decoder 240 in FIG. 2A may decode row addresses to activate the row address corresponding to the target memory cell row, and the word line driver may provide the word line driving voltage to the word line coupled to the target memory cell row based on the row address corresponding to the target memory cell row to complete the activation operation.

As an example, the memory device may also pre-charge the column address corresponding to the target memory cell row in response to the pre-charge command. For example, the column decoder 250 in FIG. 2A may decode column addresses to select the column address corresponding to the target memory cell row, and the bit line driver may provide the pre-charge voltage to the bit line coupled to the target memory cell row based on the column address corresponding to the target memory cell row to complete the pre-charge operation.

In some examples, the controller 310 is further configured to: send a plurality of activation commands to the memory device, wherein one activation command is configured to instruct to activate one row address; and randomly latch the row address corresponding to at least one activation command based on a generated random number.

Referring to FIGS. 5 and 6, the controller 310 may send a plurality of activation commands to the memory device. As an example, the controller 310 may generate an access command based on the received access request from the host and send the access command to the memory device, wherein the access request includes at least one of a read request and a write request. As another example, the controller 310 may internally generate an access command or a refresh command and send the access command or the refresh command to the memory device. In the above two examples, the access command or the refresh command may each include an activation command and other operation commands, for example, a read command, a write command, or the like.

The memory device may activate a corresponding row address in response to the respective activation command, e.g., the memory device may activate corresponding row address Addr1, a row address Addr2, a row address AddrX, . . . , a row address AddrY, etc., in response to the respective activation command in FIG. 6. As an example, the row decoder 240 in FIG. 2A may decode the row address to activate the respective target row address, and the word line driver may provide a word line driving voltage to the word line corresponding to the row address based on the row address. It should be noted that, the row addresses indicated, by the respective activation command, to be activated may be the same or different, and a plurality of activation commands may be sent to the memory device continuously or intermittently, which is not particularly limited in the present disclosure.

The controller 310 may further generate a random number, and latch the row address corresponding to the at least one activation command based on the generated random number. For ease of understanding, the following takes the random number being X, a number of activation commands being Z, and X and Z both being an integer greater than 1 as an example for illustration.

As an example, referring to FIG. 6, if X≤Z<k*X, and k is an integer greater than 1, the controller 310 may latch a row address AddrX1 corresponding to the X-th activation command, a row address AddrX2 corresponding to the 2X-th activation command, and a row address AddrX (k−1) corresponding to the (k−1)-th activation command, respectively. It should be noted that, when the value of k is 2, the controller 310 may only latch the row address AddrX1 corresponding to the X-th activation command.

In addition, if the Z activation commands are sent in multiple batches, for example, the Z activation commands are sent in two batches, where Z1 activation commands are sent in the first batch, Z2 activation commands are sent in the second batch, both Z1 and Z2 are integers greater than 1, and Z1<X≤Z1+Z2≤Z. The controller 310 may not latch the row address in a case that the Z1 activation commands are sent in the first batch, and latch the row address corresponding to the respective activation command in a case that the sum of a sequence number of a certain activation command sent in the second batch and Z1 is an integer multiple of the random number X.

It may be understood that, in an example of the present disclosure, the plurality of activation commands may also be sent to the memory device in multiple batches, and the controller 310 may accumulate the number of the activation commands sent in multiple batches, and latch the row address corresponding to the respective activation command in a case that the accumulated number of the activation commands is an integer multiple of the random number.

In an example of the present disclosure, the controller 310 generates a random number, and randomly latches the row address corresponding to the at least one activation command based on the generated random number, thereby increasing the randomness of the latching of the row address. In this way, hackers or other users with restricted access may be prevented from performing a row hammer attack by using the security vulnerability of the row hammer effect, which facilitates improving the reliability of the data and the security and stability of the memory system.

In some examples, referring to FIG. 5, the controller 310 includes a random number generating circuit 311. The random number generating circuit 311 is configured to generate a random number based on the memory system being powered on.

In an example of the present disclosure, the random number generating circuit 311 may generate any random number in a process of performing power-on initialization by the memory system or in a case that the memory system completes power-on initialization, where the random number may be an integer greater than 1. In addition, the random number generating circuit 311 may further update the generated random number, and the random number after updating and the random number before updating may be the same or different.

As an example, the random number after updating and the random number before updating are different. For example, in FIG. 6, the random number before updating is X, the random number after updating is Y, both X and Y are integers greater than 1, and X and Y are different. Before the random number X is updated, the controller 310 may latch the row address corresponding to the respective activation command, for example, latch the row address AddrX1 and the row address AddrX2, in a case that the accumulated number of activation commands is an integer multiple of X. After the random number X is updated to Y, the controller 310 may latch the row address corresponding to the respective activation command, for example, latch the row address AddrY1, in a case that the accumulated number of activation commands is an integer multiple of Y. In this way, the latching of the row address may be more random. For example, the controller 310 does not follow a fixed pattern to latch the row address, which prevents the hacker or other users with restricted access from finding the fixed pattern for the controller 310 to prevent the row hammer problem, thereby avoiding the hacker or other users with restricted access to perform the row hammer attack by using the fixed pattern.

In some examples, referring to FIG. 5, the controller 310 further includes a power-on circuit 318 coupled to the random number generating circuit 311. The power-on circuit 318 is configured to generate a random number control signal based on the memory system being powered on, where the random number control signal is configured to indicate to generate a random number. The random number generating circuit 311 may receive the random number control signal generated by the power-on circuit 318, and generate a random number. The power-on circuit 318 may also perform a power-on initialization operation based on the memory system being powered on.

In some examples, the random number generating circuit 311 includes a plurality of random number generating sub-circuits and a random number operating circuit, and each of the plurality of random number generating sub-circuits is coupled to the random number operating circuit. The random number generating sub-circuit is configured to: generate an initial random number based on the memory system being powered on; and the random number operating circuit is configured to: perform an operation on the initial random number generated by the respective random number generating sub-circuit to generate a random number.

In an example of the present disclosure, the respective random number generating sub-circuit may generate an initial random number in a process of performing power-on initialization by the memory system or in a case that the memory system completes power-on initialization. The initial random numbers generated by any two of the plurality of random number generating sub-circuits may be the same or different. The random number operating circuit performs operations on the initial random number generated by the respective random number generating sub-circuit to obtain the random number. The operations may include an addition operation, subtraction operation, multiplication operation, division operation, or other operations. In addition, the random number generating sub-circuit may further update the generated initial random number to update the random number.

In some examples, referring to FIG. 5, the controller 310 further includes a row address latching circuit 312 coupled to the random number generating circuit 311. The row address latching circuit 312 is configured to: latch the row addresses corresponding to the at least one activation command based on the generated random number; where the count of the activation commands corresponding to the latched row address is an integer multiple of the random number.

In an example of the present disclosure, the row address latching circuit 312 may temporarily store the row addresses corresponding to the activation command whose count is an integer multiple of the random number in a case that the accumulated number of the activation commands is an integer multiple of the random number (for example, the count of the activation commands is an integer multiple of the random number). In other words, the row address latching circuit 312 may randomly latch the one or more row addresses based on the random number, thereby increasing the randomness of the latching of the row address. The row address latching circuit 312 includes any latch that can implement the latching of row address.

As an example, referring to FIG. 6, the row address latching circuit 312 may latch the row address AddrX1 corresponding to the X-th activation command, the row address AddrX2 corresponding to the 2X-th activation command, and the row address AddrX(k−1) corresponding to the (k−1)-th activation command, respectively. It should be noted that, in a case that the value of k is 2, the row address latching circuit 312 may only latch the row address AddrX1 corresponding to the X-th activation command.

In some examples, referring to FIG. 5, the controller 310 further includes a row address counting circuit 313 coupled to the row address latching circuit 312. The row address counting circuit 313 is configured to: increase the count data corresponding to the latched row address based on the latched row address being hit.

In an example of the present disclosure, the row address counting circuit 313 may record the count data corresponding to the respective buffered row addresses, and increment the count data corresponding to the latched row address by 1 in a case that the latched row address is hit. The latched row address being hit indicates that the latched row address is present in the plurality of buffered row addresses.

In some examples, the row address latching circuit 312 is further configured to: compare the latched row address with the plurality of buffered row addresses to generate a comparison result; where the comparison result is configured to indicate whether the latched row address is hit.

In an example of the present disclosure, the row address latching circuit 312 may further compare the latched row address with the plurality of buffered row addresses to generate a comparison result. If the comparison result indicates that the latched row address is present in the plurality of buffered row addresses, it indicates that the row address latched in the row address latching circuit 312 is hit. In this case, the row address counting circuit 313 may increase the count data corresponding to the latched row address, for example, increment the count data corresponding to the latched row address by 1. Otherwise, if the comparison result indicates that the latched row address is not present in the plurality of buffered row addresses, it indicates that the latched row address is missed. In this case, it needs to further determine whether to buffer the missed row address (for example, the row address latched in the row address latching circuit 312).

Taking latching the row address AddrX1 corresponding to the X-th activation command as an example, if the row address AddrX1 is hit, the row address counting circuit 313 increments the count data corresponding to the hit row address by 1. Otherwise, if the row address AddrX1 is missed, it needs to further determine whether to buffer the row address AddrX1

It should be noted that, if the row address latching circuit 312 latches the same row address for multiple times and the row address is present in the plurality of buffered row addresses, then the row address counting circuit 313 needs to increment the count data corresponding to the row address by 1 each time the row address is latched.

In some examples, referring to FIG. 5, the controller 310 further includes a row address buffering circuit 314 coupled to the row address latching circuit 312 and the row address counting circuit 313, respectively. The row address buffering circuit 314 is configured to: determine whether to buffer the latched row address based on the latched row address is missed. The row address counting circuit 313 is further configured to: increase the count data corresponding to the buffered row addresses based on the latched row address being buffered.

In a case that the row address latched by the row address latching circuit 312 is missed, the row address buffering circuit 314 may determine whether to buffer the missed row address. In a case the row address buffering circuit 314 buffers the missed row address, for example, the missed row address is buffered in the row address buffering circuit 314 for the first time, the row address counting circuit 313 may set the count data corresponding to the row address that is buffered in the row address buffering circuit 314 for the first time to 1.

In some examples, the row address buffering circuit 314 is configured to: buffer the latched row address based on the latched row address is missed and a buffer capacity of the row address buffering circuit 314 is met.

In an example of the present disclosure, in a case that the row address latched by the row address latching circuit 312 is missed, the row address buffering circuit 314 may determine whether to buffer the missed row address based on whether the current buffer capacity is met. In an example, if the current buffer capacity of the row address buffering circuit 314 is met, the missed row address may be buffered. Otherwise, if the current buffer capacity of the row address buffering circuit 314 is not met, the missed row address may not be buffered.

It should be noted that, if the current buffer capacity is greater than or equal to the capacity required to buffer the missed row address, it indicates that the current buffer capacity is met. Otherwise, if the current buffer capacity is less than the capacity required to buffer the missed row address, it indicates that the current buffer capacity is not met, for example, the row address buffer resource is insufficient. Current buffer capacity=total capacity of the row address buffering circuit 314−total capacity of buffered data in the row address buffering circuit 314. It should be understood that the total capacity of the buffered data in the row address buffering circuit 314 is less than or equal to the total capacity of the row address buffering circuit 314.

In some examples, referring to FIG. 5, the controller 310 includes a row address extracting circuit 319. The row address extracting circuit 319 is configured to: randomly extract one target row address among the M target row addresses based on the maximum count data being less than or equal to a preset threshold.

In an example of the present disclosure, M is an integer greater than 1, for example, the maximum count data corresponds to a plurality of target row addresses. In a case that the maximum count data is less than or equal to the preset threshold, the row address extracting circuit 319 may randomly extract one target row address from among the plurality of target row addresses, and use the extracted target row address as the aggressor row address. In this way, randomness of target row address extraction is increased, and hackers or other users with restricted access, etc., may be prevented from performing a row hammer attack by means of the security vulnerability of the row hammer effect, which facilitates improving the reliability of the data and the security and stability of the memory system.

In some examples, the row address extracting circuit 319 is further configured to: extract the M target row addresses based on the maximum count data being greater than a preset threshold.

In an example of the present disclosure, M is an integer greater than 1, for example, the maximum count data corresponds to a plurality of target row addresses. In a case that the maximum count data is greater than the preset threshold, the row address extracting circuit 319 may extract a plurality of target row addresses corresponding to the maximum count data, and use the extracted plurality of target row addresses as the aggressor row addresses.

As an example, the preset threshold may be an integer greater than 1, for example, the preset threshold may be 1, 2, 5, 10, 15, or 20, etc. In a practical application, the preset threshold may be set reasonably according to actual conditions, which is not particularly limited in the present disclosure.

In some examples, the row address extracting circuit 319 includes a first comparing circuit and an extracting circuit coupled to the first comparing circuit. The first comparing circuit is configured to: compare the maximum count data with the preset threshold to generate a comparison result. The extracting circuit is configured to: extract the one target row address or the M target row addresses based on the comparison result.

In an example of the present disclosure, the first comparing circuit may compare the maximum count data with the preset threshold to generate the comparison result. If the comparison result indicates that the maximum count data is less than or equal to the preset threshold, indicating that the probability that respective target row addresses corresponding to the maximum count data cause the row hammer problem to be occurred in the DRAM device is relatively low, the extracting circuit may extract only one target row address. Otherwise, if the comparison result indicates that the maximum count data is greater than the preset threshold, indicating that the probability that respective target row addresses corresponding to the maximum count data cause the row hammer problem to be occurred in the DRAM device is relatively high, the extracting circuit may extract a plurality of target row addresses corresponding to the maximum count data. In this way, one target row address or M target row addresses may be reasonably selected as the aggressor row address(es) based on the comparison result between the maximum count data and the preset threshold. The first comparing circuit includes, but is not limited to, a comparator.

In some examples, referring to FIG. 5, the row address extracting circuit 319 is coupled to the row address buffering circuit 314. The row address buffering circuit 314 is configured to: buffer the respective row addresses. The extracting circuit is configured to: extract the target row address from the row address buffering circuit 314 based on the comparison result.

In an example of the present disclosure, the row address buffering circuit 314 may buffer a plurality of row addresses, and the plurality of row addresses buffered by the row address buffering circuit 314 are the respective buffered row addresses. If the comparison result indicates that the maximum count data is less than or equal to the preset threshold, the extracting circuit may randomly extract one target row address from the row address buffering circuit 314. Otherwise, if the comparison result indicates that the maximum count data is greater than the preset threshold, the extracting circuit may extract the M target row addresses from the row address buffering circuit 314.

In some examples, referring to FIG. 5, the row address extracting circuit 319 is coupled to the row address counting circuit 313. The row address extracting circuit 319 further includes a second comparing circuit coupled to the first comparing circuit. The row address counting circuit 313 is configured to: generate the count data corresponding to the respective buffered row addresses. The second comparing circuit is configured to: compare the count data generated by the row address counting circuit 313 to determine the maximum count data. The process of generating the count data by the row address counting circuit 313 may be referred to the foregoing related description, and details are not described herein again.

As an example, the second comparing circuit may sort the count data corresponding to the respective buffered row addresses, and find the count data with the highest sorting, thereby determining the maximum count data. Certainly, in another example, the second comparing circuit may also compare the count data corresponding to the respective buffered row addresses to determine the maximum count data. The second comparing circuit includes, but is not limited to, a comparator.

In some other examples, both M and N are 1. In an example of the present disclosure, the maximum count data corresponds to one row address, and the controller 310 may directly extract one row address corresponding to the maximum count data and use the extracted row address as the aggressor row address.

In some examples, the row address buffering circuit 314 is further configured to: delete the buffered row addresses after the target row address is extracted, and the row address counting circuit 313 is further configured to: reset the count data corresponding to the buffered row addresses.

In an example of the present disclosure, after the target row address is extracted, the row address buffering circuit 314 may delete the buffered row addresses. For example, in a case that the controller 310 sends the row hammer refresh operation command to the memory device, the row address buffering circuit 314 may delete the buffered row addresses. In addition, the row address counting circuit 313 may reset the count data corresponding to the buffered row addresses, for example, reset the count data corresponding to the deleted row addresses to 0 or delete the count data corresponding to the row addresses.

In some examples, referring to FIG. 5, the controller 310 further includes a row hammer refresh operation command generating circuit 315. The row hammer refresh operation command generating circuit 315 is coupled to the row address extracting circuit 319. The row hammer refresh operation command generating circuit 315 is configured to: generate the row hammer refresh operation command based on extracting the N target row addresses.

In an example of the present disclosure, in a case that the row address extracting circuit 319 extracts the N target row addresses, the row hammer refresh operation command generating circuit 315 may determine the extracted N target row addresses as the aggressor row addresses and generate the victim row address based on the aggressor row addresses, thereby generating the row hammer refresh operation command including the victim row address. The row hammer refresh operation command may be sent to the memory device through a command outputting circuit 316 or the device interface 130 as shown in FIG. 1.

In some examples, referring to FIG. 5, the controller 310 further includes a command outputting circuit 316 coupled to the row hammer refresh operation command generating circuit 315. The command outputting circuit 316 is configured to: output the row hammer refresh operation command based on a data transmission operation on a bank, to which the target memory cell row belongs, having been completed.

In an example of the present disclosure, the command outputting circuit 316 is configured to output the row hammer refresh operation command generated by the row hammer refresh operation command generating circuit 315. In an example, the controller 310 may, before sending the row hammer refresh operation command to the memory device, first confirm whether the data transmission operation on the bank, to which the target memory cell row belongs, is currently being performed. If the data transmission operation on the bank, to which the target memory cell row belongs, has been completed, the command outputting circuit 316 outputs the row hammer refresh operation command to the memory device. The data transmission operation includes at least one of a read operation and a write operation.

It should be noted that the command outputting circuit 316 may further output other operation commands. The command outputting circuit 316 may constitute a part of the device interface 130 shown in FIG. 1, or the command outputting circuit 316 and the device interface 130 shown in FIG. 1 may be two separate circuits in the controller 310, which is not specifically limited in the present disclosure.

In some examples, the command outputting circuit 316 is further configured to: delay outputting the row hammer refresh operation command based on the data transmission operation on the bank, to which the target memory cell row belongs, is being performed.

In an example of the present disclosure, if the data transmission operation on the bank, to which the target memory cell row belongs, is being performed, the command outputting circuit 316 delays outputting the row hammer refresh operation command to the memory device, for example, the row hammer refresh operation command is output after being delayed for a certain period of time.

In some examples, referring to FIG. 5, the controller 310 further includes a determining circuit 317 coupled to the command outputting circuit 316. The determining circuit 317 is configured to: determine whether the data transmission operation on the bank, to which the target memory cell row belongs, is being performed.

In an example of the present disclosure, the determining circuit 317 may determine the state of the bank to which the target memory cell row belongs and generate a determination result. If the determination result indicates that the data transmission operation on the bank, to which the target memory cell row belongs, has been completed, it indicates that the row hammer refresh operation may be currently performed on the target memory cell row, so the command outputting circuit 316 outputs the row hammer refresh operation command. Otherwise, if the determination result indicates that the data transmission operation on the bank, to which the target memory cell row belongs, is being performed, it indicates that it needs to wait currently for the data transmission operation on the bank, to which the target memory cell row belongs, to be completed, so the command outputting circuit 316 delays outputting the row hammer refresh operation command.

In some examples, the command outputting circuit 316 is coupled to the random number generating circuit 311. The command outputting circuit 316 is further configured to: output a plurality of refresh commands in a refresh cycle, wherein the refresh command is configured to instruct to perform a refresh operation on at least one of the plurality of memory cell rows. The random number generating circuit 311 is further configured to: update the generated random number based on the refresh command being output.

In an example of the present disclosure, the command outputting circuit 316 may output a plurality of refresh commands (for example, the normal refresh commands shown in FIG. 4) in a refresh cycle, and the memory device performs a refresh operation on at least one of the plurality of memory cell rows based on the refresh command. The refresh operation is typically performed in units of rows, for example, data is rewritten by activating the memory cell row indicated by the refresh command to maintain data stored in the DRAM memory cells. In a case that the command outputting circuit 316 outputs the refresh command, the random number generating circuit 311 may update the generated random number, for example, update the random number X to Y.

An example of the present disclosure provides a memory system, the memory system includes a controller and a memory device coupled to the controller. The memory device includes a plurality of memory cell rows, and the memory cell row includes a plurality of memory cells. The controller is configured to: determine maximum count data among count data corresponding to respective buffered row addresses based on a refresh command being sent to the memory device; obtain M target row addresses corresponding to the maximum count data from among the respective buffered row addresses, wherein M is an integer greater than 0, and M is less than or equal to a total number of the respective buffered row addresses; and extract N target row addresses from among the obtained M target row addresses, and use the extracted N target row addresses as aggressor row addresses, wherein N is an integer greater than 0, and N is less than or equal to M. In this way, in a first aspect, the controller can obtain, in advance, target row addresses which may cause a row hammer problem to be occurred in the DRAM device, and extract one or more target row addresses from the obtained target row addresses as the aggressor row address, so as to facilitate mitigating or even avoiding the occurrence of the row hammer problem in the DRAM device, thereby improving the reliability of the data. In a second aspect, through actively avoiding the row hammer problem by the controller, the traditional passive prevention within the DRAM can be changed to active prevention by the controller, which can actively prevent, in advance, the potential occurrence of row hammer errors in the DRAM, which facilitates reducing the possibility that the row hammer problem occurs in the memory device. In a third aspect, the randomness of the latching and extracting of the row addresses is increased, and hackers or other users with restricted access, etc., may be prevented from performing a row hammer attack by means of the security vulnerability of the row hammer effect, which facilitates improving the reliability of the data and the security and stability of the memory system. In a fourth aspect, the controller hardware automatically realizes the operations, basically without the involvement of software or changes of any software process, thus not producing any impact on the usage and operation of an external system and the controller. In a fifth aspect, through using the row hammer refresh operation command that combines the row hammer activation command and the pre-charge command to prevent the row hammer problem of DRAM, rather than using a conventional refresh command, the efficiency of DRAM utilization and the flexibility of DRAM utilization can be improved.

Based on the foregoing memory system, an example of the present disclosure provides a controller, the controller includes: a row address buffering circuit, a row address counting circuit, and a row address extracting circuit, the row address buffering circuit is configured to: buffer a plurality of row addresses, the row address counting circuit is coupled to the row address buffering circuit, and the row address counting circuit is configured to: generate count data corresponding to respective buffered row addresses, the row address extracting circuit is coupled to the row address buffering circuit and the row address counting circuit respectively, and the row address extracting circuit is configured to: determine maximum count data among count data corresponding to the respective buffered row addresses based on a refresh command being sent to a memory device by the controller; obtain M target row addresses corresponding to the maximum count data from among the respective buffered row addresses, wherein M is an integer greater than 0, and M is less than or equal to a total number of the respective buffered row addresses; and extract N target row addresses from among the obtained M target row addresses, and use the extracted N target row addresses as aggressor row addresses, wherein N is an integer greater than 0, and N is less than or equal to M.

In some examples, M is an integer greater than 1, and the row address extracting circuit is configured to: randomly extract one target row address among the M target row addresses based on the maximum count data being less than or equal to a preset threshold.

In some examples, the row address extracting circuit is further configured to: extract the M target row addresses based on the maximum count data being greater than the preset threshold.

In some examples, the row address extracting circuit includes a first comparing circuit and an extracting circuit coupled to the first comparing circuit; the first comparing circuit is configured to: compare the maximum count data with the preset threshold to generate a comparison result; and the extracting circuit is configured to: extract the one target row address or the M target row addresses based on the comparison result.

In some examples, the extracting circuit is configured to: extract the target row address from the row address buffering circuit based on the comparison result.

In some examples, the row address extracting circuit further includes a second comparing circuit coupled to the first comparing circuit, and the second comparing circuit is configured to: compare the count data generated by the row address counting circuit to determine the maximum count data.

In some examples, both M and N are 1.

In some examples, the row address buffering circuit is further configured to: delete the buffered row addresses after the target row address is extracted; and the row address counting circuit is further configured to: reset the count data corresponding to the buffered row addresses.

In some examples, the controller is further configured to: generate a victim row address adjacent to the aggressor row addresses, wherein a target memory cell row, to which the victim row address points, is adjacent to memory cell rows, to which the aggressor row addresses point; and send a row hammer refresh operation command including the victim row address to the memory device, wherein the row hammer refresh operation command is configured to instruct to perform a row hammer refresh operation on the target memory cell row.

In some examples, the row hammer refresh operation command includes a row hammer activation command and a pre-charge command, and wherein the row hammer activation command is configured to instruct to perform an activation operation on the row address corresponding to the target memory cell row, and the pre-charge command is configured to instruct to perform a pre-charge operation on a column address corresponding to a selected memory cell among a plurality of memory cells in the target memory cell row.

In an example of the present disclosure, the controller may be the same as the controller in the memory system in any one of the above examples, and technical effects that can be achieved by the memory system in the above examples may also be achieved by the controller, and details are not described herein again. The circuits in the controller in the above examples are described in detail in the related examples of the memory system, and will not be described in detail herein.

Based on the foregoing controller, an example of the present disclosure provides an operating method of a controller.

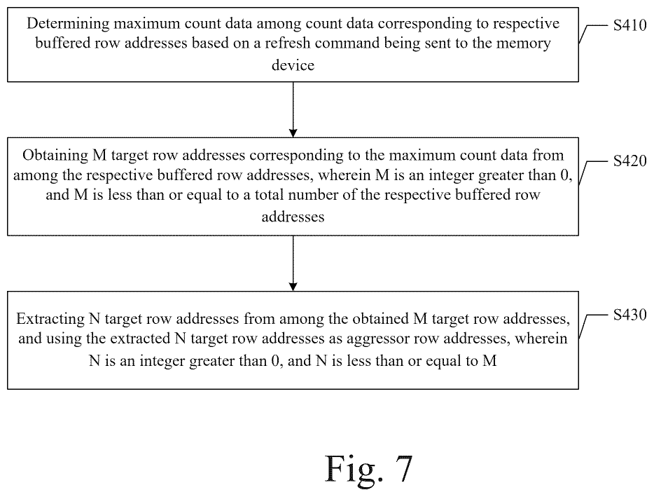

FIG. 7 is a schematic flowchart of an operating method of a controller according to an example of the present disclosure. It should be noted that the operations shown in FIG. 7 are not exclusive, and other operations may be performed before, after, or between any operations in the illustrated operations. The order of the operations shown in FIG. 7 may be adjusted according to actual needs. Referring to FIG. 7, the operating method includes at least the following operations:
S410: determining maximum count data among count data corresponding to respective buffered row addresses based on a refresh command being sent to a memory device;
S420: obtaining M target row addresses corresponding to the maximum count data from among the respective buffered row addresses, wherein M is an integer greater than 0, and M is less than or equal to a total number of the respective buffered row addresses; and
S430: extracting N target row addresses from among the obtained M target row addresses, and using the extracted N target row addresses as aggressor row addresses, wherein N is an integer greater than 0, and N is less than or equal to M.

In some examples, M is an integer greater than 1, and operation S430 includes: randomly extracting one target row address among the M target row addresses based on the maximum count data being less than or equal to a preset threshold.

In some examples, operation S430 further includes: extracting the M target row addresses based on the maximum count data being greater than the preset threshold.

In some examples, operation S430 further includes: comparing the maximum count data with the preset threshold to generate a comparison result; and extracting the one target row address or the M target row addresses based on the comparison result.

In some examples, both M and N are 1.

In some examples, operation S410 includes: comparing the count data corresponding to the respective buffered row addresses to determine the maximum count data.

In some examples, the operating method further includes: deleting the buffered row addresses after the target row address is extracted; and resetting the count data corresponding to the buffered row addresses.

In some examples, the operating method further includes: generating a victim row address adjacent to the aggressor row addresses, wherein a target memory cell row, to which the victim row address points, is adjacent to memory cell rows, to which the aggressor row addresses point; and sending a row hammer refresh operation command including the victim row address to the memory device, wherein the row hammer refresh operation command is configured to instruct to perform a row hammer refresh operation on the target memory cell row.

In some examples, the row hammer refresh operation command includes a row hammer activation command and a pre-charge command, and wherein the row hammer activation command is configured to instruct to perform an activation operation on the row address corresponding to the target memory cell row, and the pre-charge command is configured to instruct to perform a pre-charge operation on a column address corresponding to a selected memory cell among a plurality of memory cells in the target memory cell row.

In an example of the present disclosure, the operating method of the controller may be may be performed by the controller in any one of the above examples, and technical effects that can be achieved by the controller in the above examples may also be achieved by the operating method, and details are not described herein again. The example of each operation in the operating method in the above examples is described in detail in the related examples of the memory system, and will not be described in detail herein.

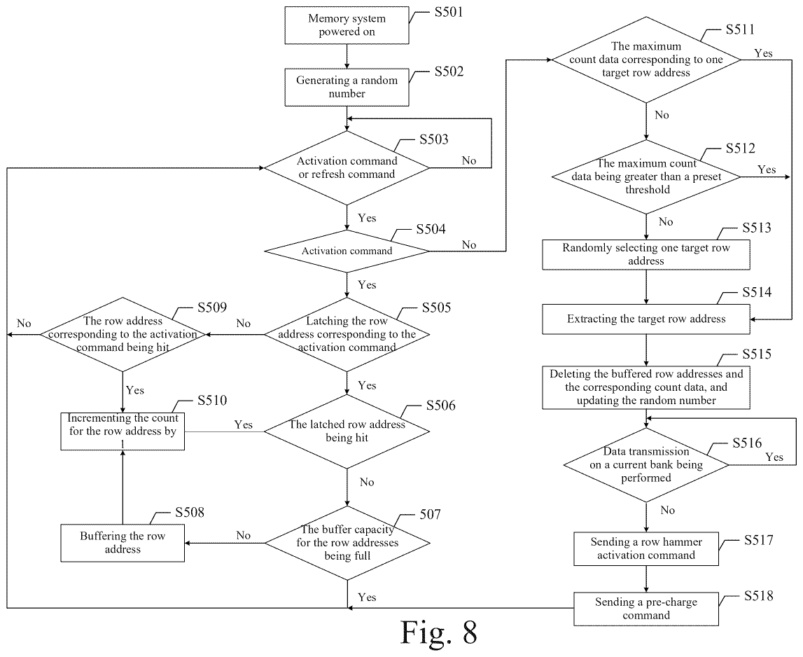

FIG. 8 is an operation flowchart of a controller according to an example of the present disclosure. For ease of understanding the above operating method, the following describes the operating method of the controller according to the examples of the present disclosure with reference to FIG. 5 and FIG. 8.

Referring to FIG. 8, in operation S501: the memory system is powered on. In an example, the power-on circuit 318 in FIG. 5 may perform a power-on initialization operation based on the memory system being powered on, and generate a random number control signal and send the random number control signal to the random number generating circuit 311 in FIG. 5.

In operation S502: a random number is generated. In an example, the random number generating circuit 311 in FIG. 5 generates a random number based on the received random number control signal and sends the random number to the row address latching circuit 312 in FIG. 5, where the random number is an integer greater than 1.

In operation S503: it is determined whether the controller sends an activation command or a refresh command to the memory device. In an example, if the controller 310 in FIG. 5 does not send an activation command or a refresh command to the memory device 320, the process returns to operation 503, e.g., continuing to wait for the activation command or the refresh command. Otherwise, if the controller 310 sends the activation command or the refresh command to the memory device 320, operation S504 is performed.

In operation S504: it is determined whether the controller sends the activation command. In an example, if the controller 310 in FIG. 5 sends the activation command, operation S505 is performed. Otherwise, if the controller 310 sends the refresh command instead of the activation command, operation S511 is performed.

In operation S505: it is determined whether to latch the row address corresponding to the activation command. In an example, if the count of the current activation command is an integer multiple of the random number, the row address latching circuit 312 in FIG. 5 latches the row address corresponding to the current activation command, and operation S506 is performed. Otherwise, if the count of the current activation command is not an integer multiple of the random number, operation S509 is performed.

In operation S506: it is determined whether the latched row address is hit. In an example, if the latched row address is present in the plurality of row addresses buffered by the row address buffering circuit 314 in FIG. 5, it indicates that the latched row address is hit and operation S510 is performed. Otherwise, if the latched row address is not present in the plurality of row addresses buffered by the row address buffering circuit 314 in FIG. 5, it indicates that the latched row address is missed and operation S507 is performed.

In operation S507: it is determined whether the buffer capacity for the row addresses is full. In an example, if the buffer capacity of the row address buffering circuit 314 in FIG. 5 is not full (for example, the current buffer capacity is greater than or equal to the capacity required for buffering the missed row addresses), operation S508 is performed. Otherwise, if the buffer capacity of the row address buffering circuit 314 in FIG. 5 is full (for example, the current buffer capacity is less than the capacity required for buffering the missed row addresses), the row address which is latched and missed is ignored, and the process returns to operation S503 to continue to wait for the next activate command or refresh command.

In operation S508: the row address is buffered. In an example, in a case that the buffer capacity of the row address buffering circuit 314 in FIG. 5 is not full, the row address buffering circuit 314 may buffer the row address which is latched and missed, and operation S510 is performed.

In operation S509: it is determined whether the row address corresponding to the activation command is hit. In an example, if the count of the current activation command is not an integer multiple of the random number, but there is a row address corresponding to the current activation command among the plurality of row addresses that have been buffered by the row address buffering circuit 314 in FIG. 5, it indicates that the row address corresponding to the current activation command is hit, and operation S510 is performed.

In operation S510: the count for the row address is incremented by 1. In an example, if the latched row address is hit, the row address counting circuit 313 in FIG. 5 may increment the count data corresponding to the hit row address by 1. If the row address buffering circuit 314 buffers the row address which is latched and missed, for example, the row address buffering circuit 314 buffers the missed row address for the first time, the row address counting circuit 313 in FIG. 5 may set the count data corresponding to the row address that is buffered for the first time to 1. If the row address corresponding to the activate command whose count is not an integer multiple of the random number is hit, the row address counting circuit 313 may also increment the count data corresponding to the row address by 1.

In operation S511: it is determined whether the maximum count data corresponds to one target row address. In an example, if the controller 310 sends a refresh command to the memory device 320, the maximum count data among the count data corresponding to the respective buffered row addresses is determined, and M target row addresses corresponding to the maximum count data are obtained from the respective buffered row addresses. If M is 1, for example, the maximum count data corresponds to one target row address, operation S514 is performed. Otherwise, if M is an integer greater than 1, for example, the maximum count data corresponds to the plurality of target row addresses, operation S512 is performed.

In operation S512: it is determined whether the maximum count data is greater than a preset threshold. In an example, if the maximum count data is greater than the preset threshold, operation S514 is performed. Otherwise, if the maximum count data is less than or equal to the preset threshold, operation S513 is performed.

In operation S513: a target row address is randomly selected. In an example, if the maximum count data is less than or equal to the preset threshold, a target row address is randomly selected from among the plurality of target row addresses, and operation S514 is performed.

In operation S514: the target row address is extracted. In an example, if the maximum count data corresponds to one target row address, the row address extracting circuit 319 in FIG. 5 may extract one target row address corresponding to the maximum count data from the row address buffering circuit 314. If the maximum count data corresponds to a plurality of target row addresses and the maximum count data is less than or equal to the preset threshold, the row address extracting circuit 319 may randomly extract one target row address from the row address buffering circuit 314. If the maximum count data corresponds to a plurality of target row addresses and the maximum count data is greater than the preset threshold, the row address extracting circuit 319 may extract a plurality of target row addresses corresponding to the maximum count data from the row address buffering circuit 314.

In operation S515: the buffered row addresses and the corresponding count data are deleted, and the random number is updated. In an example, after the target row address(es) is (are) extracted, the row address buffering circuit 314 in FIG. 5 may delete the buffered row addresses, the row address counting circuit 313 in FIG. 5 may delete the count data corresponding to the buffered row addresses, and the random number generating circuit 311 in FIG. 5 may update the generated random number.

In operation S516: it is determined whether a data transmission operation on a current bank is being performed. If the data transmission operation on the current bank is being performed, the command outputting circuit 316 in FIG. 5 delays outputting the row hammer refresh operation command. Otherwise, if the data transmission operation on the current bank has been completed, operation S517 is performed. The current bank is a bank to which the target memory cell row belongs, and the target memory cell row is adjacent to the memory cell row to which the aggressor row address points.

In operation S517: a row hammer activation command is sent. In an example, the command outputting circuit 316 in FIG. 5 outputs the row hammer refresh operation command, the row hammer refresh operation command includes a row hammer activation command, the row hammer activation command is configured to instruct to perform an activation operation on the row address corresponding to the target memory cell row. After the activation operation is completed, operation S518 is performed.

In operation S518: a pre-charge command is sent. The row hammer refresh operation command further includes the pre-charge command, the pre-charge command is configured to instruct to perform a pre-charge operation on a column address corresponding to a selected memory cell among the plurality of memory cells in the target memory cell row. After the pre-charge operation is completed, the process returns to operation S503 and continues to wait for the next activation command or refresh command.

It may be understood that, through repeatedly performing the above operations S501 to S518, the controller may deal with the row hammer problem. For example, the controller obtains the target row address(es) which may cause the row hammer problem to be occurred in the DRAM device in advance, and extracts one or more target row addresses from the obtained target row addresses as the aggressor row addresses, so as to facilitate mitigating or even avoiding the occurrence of the row hammer problem in the DRAM device, thereby improving the reliability of the data.

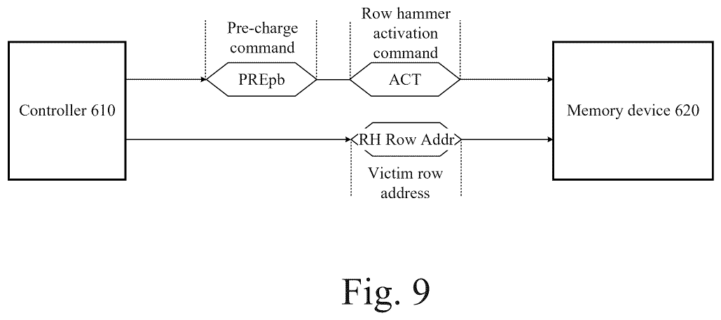

FIG. 9 is a schematic diagram of a controller sending a victim row address and a row hammer refresh operation command to a memory device according to an example of the present disclosure.

Referring to FIG. 9, a controller 610 sends a victim row address, RH Row Addr, and a row hammer refresh operation command to a memory device 620, where the row hammer refresh operation command includes a row hammer activation command, ACT, and a pre-charge command, PREpb.

In an example, the memory device 620 may perform an activation operation on a target memory cell row to which the victim row address points based on the row hammer activation command, ACT, where the activated target memory cell row is adjacent to the memory cell rows, to which the aggressor row addresses point. After the activation operation is completed, the memory device 620 may further perform a pre-charge operation on a column address corresponding to the target memory cell row based on the pre-charge command, PREpb.

As an example, the controller 610 generates two victim row addresses RH Row addr based on the row hammer address, where the generated two victim row addresses RH Row addr may be “Aggressor Row Address+1” and “Aggressor Row Address−1”, respectively.

The controller 610 sends a first row hammer activation command, ACT and a first victim row address “Aggressor Row Address+1” to the memory device 620 to activate (or turn on) the first victim row address “Aggressor Row Address+1”. After activating the first victim row address “Aggressor Row Address+1”, the controller 610 sends a first pre-charge command, PREpb, to turn off the first victim row address “Aggressor Row Address+1” to complete the row hammer refresh of the first target memory cell row, to which the first victim row address “Aggressor Row Address+1” points.

The controller 610 sends a second row hammer activation command, ACT and a second victim row address “Aggressor Row Address−1” to the memory device 620 to activate (or turn on) the second victim row address “Aggressor Row Address−1”. After activating the second victim row address “Aggressor Row Address−1”, the controller 610 sends a second pre-charge command, PREpb, to turn off the second victim row address “Aggressor Row Address−1”, thereby completing the row hammer refresh of the second target memory cell row, to which the second victim row address “Aggressor Row Address−1” points.

In another example, the row hammer refresh of the second target memory cell row may also be performed first, and then the row hammer refresh of the first target memory cell row is performed. The order of performing the row hammer refresh on the first target memory cell row and the second target memory cell row is not specifically limited in the examples of the present disclosure.

It should be noted that, although the controller 610 generates two victim row addresses, however if the memory cell row, to which the aggressor row address points, is the topmost memory cell row or the bottommost memory cell row among the plurality of memory cell rows, the memory device 620 may perform the row hammer refresh on only one of the victim row addresses. For example, the controller 610 sends the first victim row address “Aggressor Row Address+1” and the second victim row address “Aggressor Row Address−1” to the memory device 620, and the memory device 620 may perform the row hammer refresh only on the first victim row address “Aggressor Row Address+1” or the second victim row address “Aggressor Row Address−1” that is adjacent to the row hammer address.

The above descriptions are only examples of the present disclosure, but the protection scope of the present disclosure is not limited thereto. Changes or replacements that may be easily conceived by any person skilled in the art within the technical scope of the present disclosure should be covered within the protection scope of the present disclosure.

What is claimed is:

1. A memory system, comprising:
a controller; and
a memory device coupled to the controller, wherein the memory device includes a plurality of memory cell rows,
wherein the controller is configured to:
determine maximum count data among count data corresponding to respective buffered row addresses based on a refresh command being sent to the memory device;
obtain M target row addresses corresponding to the maximum count data from among the respective buffered row addresses, wherein M is an integer greater than 0, and M is less than or equal to a total number of the respective buffered row addresses; and
extract N target row addresses from among the obtained M target row addresses, and use the extracted N target row addresses as aggressor row addresses, wherein N is an integer greater than 0, and N is less than or equal to M.

2. The memory system of claim 1, wherein M is an integer greater than 1, and the controller includes a row address extracting circuit, and
the row address extracting circuit is configured to: randomly extract one target row address among the M target row addresses based on the maximum count data being less than or equal to a preset threshold.

3. The memory system of claim 2, wherein the row address extracting circuit is further configured to:
extract the M target row addresses based on the maximum count data being greater than the preset threshold.

4. The memory system of claim 2, wherein the row address extracting circuit includes a first comparing circuit and an extracting circuit coupled to the first comparing circuit;
the first comparing circuit is configured to:
compare the maximum count data with the preset threshold to generate a comparison result; and
the extracting circuit is configured to:
extract the one target row address or the M target row addresses based on the comparison result.

5. The memory system of claim 4, wherein the controller further includes a row address buffering circuit coupled to the row address extracting circuit;
the row address buffering circuit is configured to:
buffer the respective row addresses; and
the extracting circuit is configured to:
extract the target row address from the row address buffering circuit based on the comparison result.

6. The memory system of claim 5, wherein the controller further includes a row address counting circuit coupled to the row address extracting circuit, and the row address extracting circuit further includes a second comparing circuit coupled to the first comparing circuit;
the row address counting circuit is configured to:
generate the count data corresponding to the respective buffered row addresses; and
the second comparing circuit is configured to:
compare the count data generated by the row address counting circuit to determine the maximum count data.

7. The memory system of claim 6, wherein
the row address buffering circuit is further configured to:
delete the buffered row addresses after the target row address is extracted; and
the row address counting circuit is further configured to:
reset the count data corresponding to the buffered row addresses.

8. The memory system of claim 1, wherein both M and N are 1.

9. The memory system of claim 1, wherein the controller is further configured to:
generate a victim row address adjacent to the aggressor row addresses, wherein a target memory cell row, to which the victim row address points, is adjacent to memory cell rows, to which the aggressor row addresses point; and
send a row hammer refresh operation command including the victim row address to the memory device, wherein the row hammer refresh operation command is configured to instruct to perform a row hammer refresh operation on the target memory cell row.

10. The memory system of claim 9, wherein the row hammer refresh operation command includes a row hammer activation command and a pre-charge command, and wherein the row hammer activation command is configured to instruct to perform an activation operation on the row address corresponding to the target memory cell row, and the pre-charge command is configured to instruct to perform a pre-charge operation on a column address corresponding to a selected memory cell among a plurality of memory cells in the target memory cell row.

11. The memory system of claim 1, wherein the memory device comprises a dynamic random access memory.

12. A controller, comprising:
a row address buffering circuit configured to:
buffer a plurality of row addresses;
a row address counting circuit coupled to the row address buffering circuit and configured to:
generate count data corresponding to respective buffered row addresses; and
a row address extracting circuit coupled to the row address buffering circuit and the row address counting circuit respectively and configured to:
determine maximum count data among count data corresponding to the respective buffered row addresses based on a refresh command being sent to a memory device by the controller;
obtain M target row addresses corresponding to the maximum count data from among the respective buffered row addresses, wherein M is an integer greater than 0, and M is less than or equal to a total number of the respective buffered row addresses; and
extract N target row addresses from among the obtained M target row addresses, and use the extracted N target row addresses as aggressor row addresses, wherein N is an integer greater than 0, and N is less than or equal to M.

13. The controller of claim 12, wherein M is an integer greater than 1, and the row address extracting circuit is configured to:
randomly extract one target row address among the M target row addresses based on the maximum count data being less than or equal to a preset threshold.

14. The controller of claim 13, wherein the row address extracting circuit is further configured to:
extract the M target row addresses based on the maximum count data being greater than the preset threshold.

15. The controller of claim 13, wherein the row address extracting circuit includes a first comparing circuit and an extracting circuit coupled to the first comparing circuit;
the first comparing circuit is configured to:
compare the maximum count data with the preset threshold to generate a comparison result; and
the extracting circuit is configured to:
extract the one target row address or the M target row addresses based on the comparison result.

16. The controller of claim 15, wherein the extracting circuit is configured to:
extract the target row address from the row address buffering circuit based on the comparison result.

17. The controller of claim 15, wherein the row address extracting circuit further includes a second comparing circuit coupled to the first comparing circuit; and
the second comparing circuit is configured to:
compare the count data generated by the row address counting circuit to determine the maximum count data.

18. The controller of claim 12, wherein both M and N are 1.

19. An operating method of a controller, comprising:
determining maximum count data among count data corresponding to respective buffered row addresses based on a refresh command being sent to a memory device;
obtaining M target row addresses corresponding to the maximum count data from among the respective buffered row addresses, wherein M is an integer greater than 0, and M is less than or equal to a total number of the respective buffered row addresses; and
extracting N target row addresses from among the obtained M target row addresses, and using the extracted N target row addresses as aggressor row addresses, wherein N is an integer greater than 0, and N is less than or equal to M.

20. The operating method of claim 19, wherein M is an integer greater than 1, and extracting the N target row addresses from among the obtained M target row addresses comprises:
randomly extracting one target row address among the M target row addresses based on the maximum count data being less than or equal to a preset threshold.
